(19) United States
(12) Patent Application Publication
(10) Pub. No.: US 2024/0274533 A1
(43) Pub. Date: Aug. 15, 2024

(54) STRING DRIVER CONNECTIONS FOR WAFER ON WAFER PACKAGING

(71) Applicant: Micron Technology, Inc., Boise, ID (US)

(72) Inventors: Michael A. Smith, Boise, ID (US); Martin W. Popp, Boise, ID (US); Richard J. Hill, Boise, ID (US)

(21) Appl. No.: 18/416,227

(22) Filed: Jan. 18, 2024

Related U.S. Application Data
(60) Provisional application No. 63/445,971, filed on Feb. 15, 2023.

(51) Int. Cl. H01L 23/528; G11C 5/06; G11C 16/04; H01L 21/762; H01L 25/065; H01L 27/092; H01L 29/06

(52) U.S. Cl. CPC H01L 23/5283; G11C 5/063; G11C 16/0483; H01L 21/76224; H01L 25/0657; H01L 27/0922; H01L 29/0649; H01L 2225/06524

(57) ABSTRACT

A semiconductor device assembly including a first wafer having complementary metal-oxide-semiconductor (CMOS) devices, the CMOS devices including a plurality of string drivers, wherein each of the plurality of string drivers includes a field effect transistor (FET), a global word line connected to a source of the FET, and a local word line vertically passing through the FET; and a second wafer having a memory array including a plurality of word lines, each of the word lines being connected to a corresponding one of the string drivers of the first wafer through a local word line of the corresponding string driver, wherein a backside surface of the first wafer is bonded to a frontside surface of the second wafer to form a wafer-on-wafer (WOW) bonding.

### CROSS-REFERENCE TO RELATED APPLICATION(S)

The present application claims priority to U.S. Provisional Patent Application No. 63/445,971, filed Feb. 15, 2023, the disclosure of which is incorporated herein by reference in its entirety.

### TECHNICAL FIELD

The present disclosure generally relates to string drivers, and more particularly relates to string driver direct source and drain connections in wafer-on-wafer (WOW) packaging.

### BACKGROUND

Microelectronic devices generally include a wafer, e.g., a complementary metal-oxide-semiconductor (CMOS) wafer, that is bonded to a memory array wafer to form the WOW packages. The CMOS wafer and the memory array wafer can be further mounted on a package substrate or a carrier wafer and encased in a protective covering. The CMOS wafer may include integrated circuitry with a high density of very small components including processor circuits, imager devices, string drivers, and/or high voltage (HV) circuits. On the other hand, the memory array wafer may include memory arrays including NAND flash memory arrays, dynamic random-access memory (DRAM) arrays, and/or phase change memory (PCM) arrays, the memory arrays being connected to the HV circuits of the CMOS wafer for data signal and control signal transition. Conventional processes for bonding the CMOS wafer and the memory array wafer include electrically coupling the CMOS wafer HV circuits and the memory arrays through string driver circuits and forming hybrid bonds at the interface of a frontside surface of the CMOS wafer and a frontside surface of the memory array wafer, so as to form a pad over array (POA front-to-front) or a pad over CMOS (POC, front-to-front) WOW packaging.

### BRIEF DESCRIPTION OF THE DRAWINGS

FIG. 1 depicts a schematic view of a WOW bonding for semiconductor device assembly according to embodiments of the present technology.

FIG. 2 depicts a schematic view of string drivers in conventional WOW packaging.

FIG. 3A depicts a schematic view of string drivers having local word lines disposed between adjacent string drivers.

FIG. 3B depicts a schematic view of string drivers having local word lines passing there through according to embodiments of the present technology.

FIG. 4A depicts a schematic view of a CMOS wafer incoming to the WOW bonding scheme according to embodiments of the present technology.

FIG. 4B depicts a schematic view of the CMOS wafer and a memory array wafer prior to the WOW bonding process according to embodiments of the present technology.

FIG. 4C depicts a schematic view of a WOW packaging including the CMOS wafer and the memory array wafer according to embodiments of the present technology.

FIG. 5 depicts a plane view of various string drivers according to embodiments of the present technology.

FIG. 6A depicts a cross-sectional view of string drivers including corresponding local word lines according to embodiments of the present technology.

FIG. 6B depicts a cross-sectional view of string drivers including corresponding global word lines according to embodiments of the present technology.

FIG. 7 depicts a plane view of a row of string drivers having various shallow trench isolation and local deep trench isolation configurations according to embodiments of the present technology.

FIG. 8 is a flow chart illustrating a method of processing the WOW bonding for semiconductor device assembly according to embodiments of the present technology.

FIG. 9 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

WOW packaging strategy generally separates the production of CMOS devices and memory arrays. For example, CMOS devices can be processed in the CMOS wafer and memory arrays can be processed in a separate memory array wafer, without any thermal budget constraints there between. With this configuration, the CMOS devices can be processed in a relative higher temperature compared to the memory array wafer for better device performance. In addition, the CMOS wafer and memory array wafer can be bonded at some step in the fabrication flow after each of their front-end-of-line (FEOL) processes are completed.

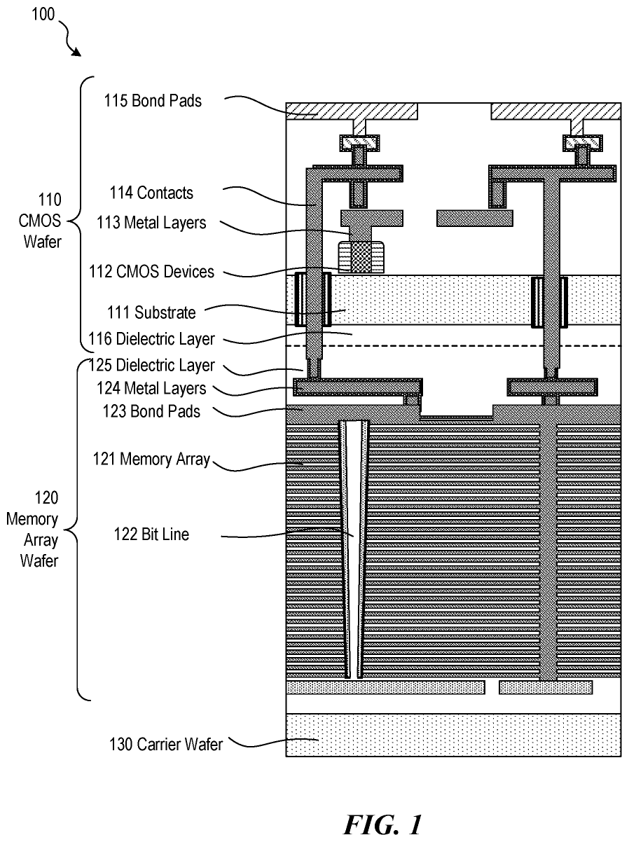

FIG. 1 depicts a schematic view of a WOW bonding scheme 100 for semiconductor device assembly according to embodiments of the present technology. The WOW package includes a CMOS wafer 110, a memory array wafer 120, and a carrier wafer 130. As shown, the CMOS wafer 110 is bonded on the memory array wafer 120, which is further mounted on the carrier wafer 120. In this WOW bonding scheme 100, a backside surface of the CMOS wafer 110 is bonded to a frontside surface of the memory array wafer 120 through a direct bonding technique, e.g., a dielectric-dielectric fusion bonding with strong covalent bonds. The CMOS wafer may include a substrate 111, a plurality of CMOS devices 112 that disposed within or above the substrate 111, a plurality of metal routing layers 113, and a plurality of bond pads 115 disposed on a frontside surface of the CMOS wafer 110. On the other hand, the memory array wafer 120 may include a memory array 121, a plurality of bit lines 122 vertically extending through the memory array 121, and a plurality of bond pads 123 each connected to corresponding one of the plurality of bit lines 122. Notably, the CMOS wafer 110 and the memory array wafer 120 includes a dielectric layer 116 and a dielectric layer 125 that are disposed on their backside surface and frontside surface, respectively. Here, the dielectric layers 116 and 125 provide electric isolation among the components included in each of the CMOS wafer 110 and the memory array wafer 120. Further, the direct bonding interface with fusion bonds between the CMOS wafer 110 and the memory array wafer 120 can be formed by attaching the dielectric layers 116 and 125 and applying heat or compressive pressures there between.

As shown in FIG. 1, the WOW bonding scheme 100 further includes electrical contacts 114 each connects one metal routing layer 113 to a corresponding one of the plurality of metal layers 124 for HV and control signal transition from the CMOS wafer 110 to the memory array wafer 120. The electrical contacts 114 can be configured to transfer high voltage or data signals to the bit line 122 or word lines (not shown) of the memory array for main operations of read and write of flash pages and erase of memory blocks. In this example, the final metal layers, e.g., the metal layers 113 of the CMOS wafer having a relatively low processing temperature (e.g., close to 300° C.), may be processed after the WOW direct bonding step. In some embodiments, the CMOS wafer is preferred to be no larger than the corresponding memory array wafer for cost reduction and packaging processes control.

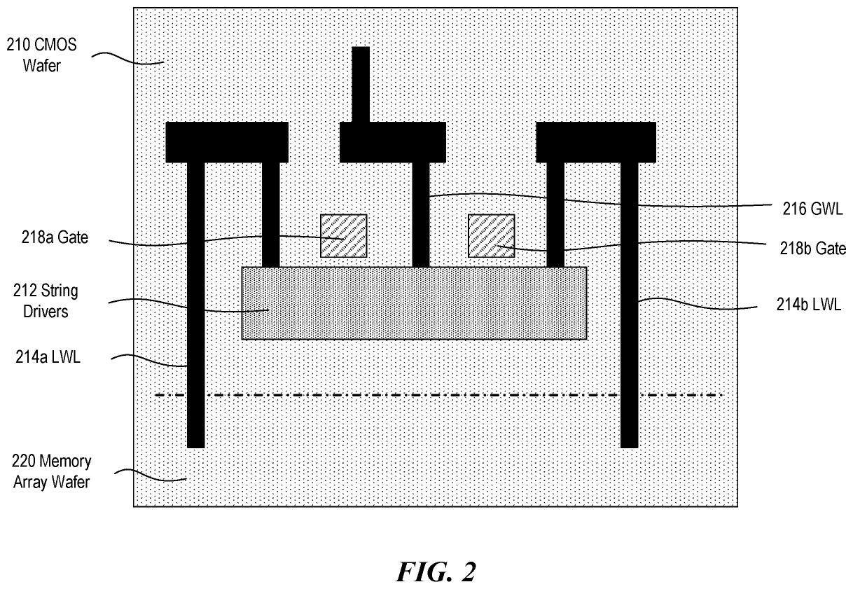

The WOW packaging strategy typically utilizes a plurality of string drivers disposed in the CMOS wafer to transfer voltage from a HV circuit to corresponding word lines of memory arrays of the memory array wafer. FIG. 2 depicts a schematic view of exemplary string drivers 200 disposed close to the backside surface of the CMOS wafer 210. Two string drivers 212 are included in this example with a shared drain region. Each of the string drivers is a high voltage transistor having a gate electrode 218a and 218b, respectively. In this example, these two string drivers 212 have a shared global word line (GWL) 216 that connects the shared drain region to a HV circuit. In addition, each of those two string drivers 212 has a dedicated local word line (LWL) 214a and 214b that each connects the source region of the string driver transistor to corresponding word line of the memory array.

In conventional single wafer process, the GWL and LWL all vertically extend from the string driver transistor to metal layers of the CMOS wafer. The GWL is further extended from metal layers to HV circuitry for voltage signal transition. To further provide interconnection and voltage transition path between string driver transistors and memory arrays, the LWLs are further extended from the CMOS wafer metal layers to the memory array, e.g., metal pads that connected to word lines of the memory array. As shown in FIG. 2, the LWLs 214a and 214b extend through dielectric regions of the CMOS wafer and are disposed between neighboring string drivers transistors. This CMOS wafer routing packing density is limited by intrinsic string driver requirements, e.g., isolation, voltage handling ability, and device performances, etc.

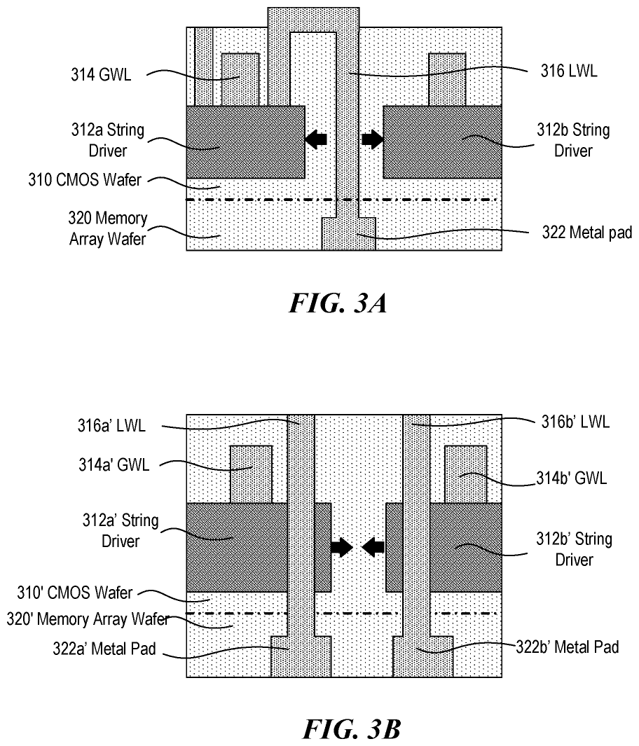

FIG. 3A depicts a schematic view of string drivers having LWL disposed between adjacent string drivers in conventional WOW packaging strategy. For example, FIG. 3A includes two string driver transistors 312a and 312b that are aligned horizontally and are disposed close to a backside surface of the CMOS wafer 310. As shown, the backside surface of the CMOS wafer 310 is bonded to the frontside surface of the memory array wafer 320. In addition, each of the string drivers 312a and 312b are connected with GWL and LWL for memory array control and data signal transition. In this example, the LWL 316 connects a drain region of the string driver 312a to a meal pad of the memory array wafer 320. Specifically, the LWL 316 firstly extend from a top surface of the drain region to a metal layer and then routed through the metal layer to the metal pad 322 for voltage signal transition. Here, the LWL 316 is disposed between the neighboring string driver transistors 312a and 312b by passing through the dielectric material there between. The LWL configuration in the conventional WOW packaging strategy limits the pitch distance of string drivers and requires an isolation control between the string driver and neighboring LWL interconnections.

To address the above-described challenges and others, the present technology includes a novel LWL connection in the WOW packaging scheme. In particular, the LWL are configured to pass through the string drivers in the present technology. Specifically, the LWL can vertically pass through a drain region of a string driver transistor to transfer voltage from the string driver transistor to corresponding metal pad of the memory array wafer. For example, FIG. 3B depicts a schematic view of string drivers having LWL passing through the drain regions according to embodiments of the present technology. As shown, the CMOS wafer 310′ is bonded to the memory array wafer 320′. The CMOS wafer 310′ includes two string driver transistors 312a′ and 312b′ each having a LWL 316a′ and 316b′ passing through its drain region. The LWL 316a′ and 316b′ transfer voltages that pass through the string driver transistors 312a′ and 312b′ to the metal pads 322a′ and 322b′, respectively. In the present technology, the distance between neighboring string drivers can be further scaled to achieve a higher CMOS device density. On the other hand, string driver devices with this configuration can provide better isolation and avoid breakdown when operating high voltages.

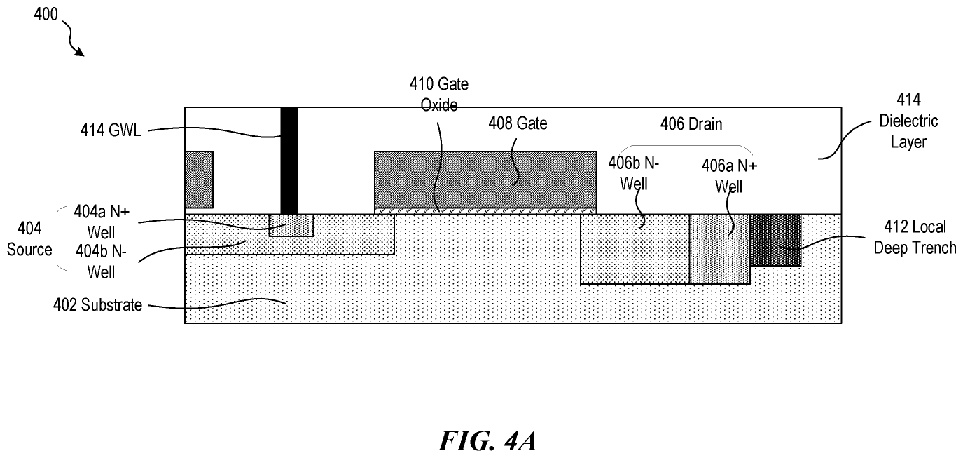

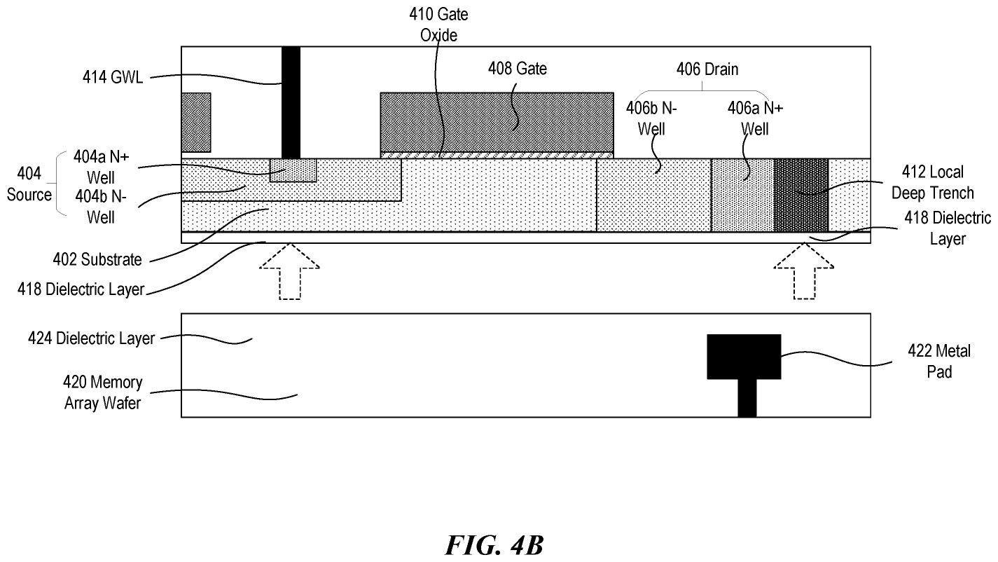

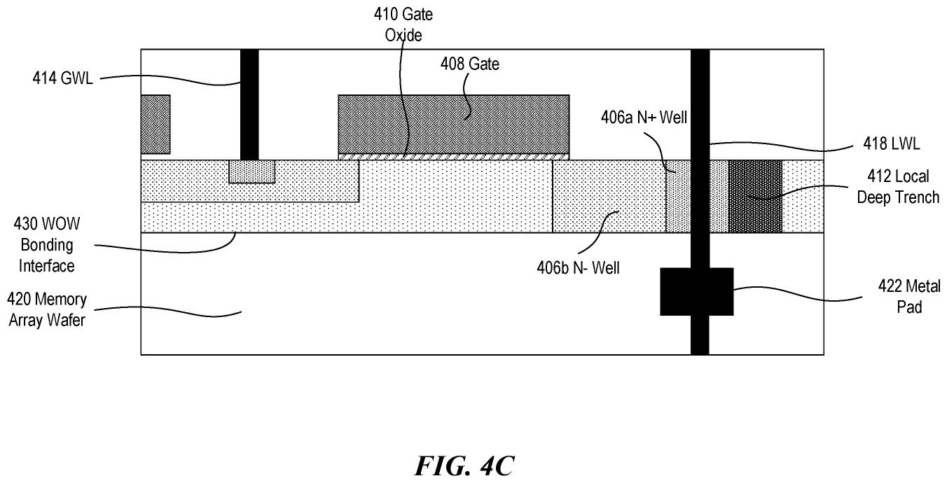

FIG. 4A depicts a schematic view of a CMOS wafer 400 incoming to the WOW bonding scheme according to embodiments of the present technology. The CMOS wafer 400 includes a plurality of string drivers each having a gate electrode 408, a source region 404, a drain region 406, and a local deep trench (LDT) region 412. The plurality of string drivers can be disposed at various locations, e.g., on a front surface of a substrate 402 of the CMOS wafer 400. In addition, the plurality of string drivers can be encapsulated by a dielectric layer 414 for electrical isolation.

In some embodiments, each of the plurality of string drivers of the incoming CMOS wafer 400 can be made of a Metal-Oxide-Semiconductor Field Effect Transistor (MOSFET). For example, FIG. 4A shows a n-channel MOSFET, in which the gate electrode 408 including a gate oxide layer 410 are disposed on the frontside surface of the substrate 402. The source region 404 and the drain region 406 are disposed at opposite ends of the gate 408. The gate electrode 408 may be composed of polysilicon, a silicide material, and/or metal composites such as WN, TiN, or TaN. The gate oxide layer 410 is disposed below the gate electrode 408 and is configured to separate the gate electrode 408 from the underlying source region 404 and drain region 406. In general, a thermal oxidation process can be used to fabricate the gate oxide layer 410 with high a dielectric constant (e.g., SiO₂, ZrO₂, and/or HfO₂). In the exemplary embodiments, the substrate 402 can be a p-type substrate (e.g., doped with Boron and/or Gallium). Further, the source region 404 may include a n-doped N+ region 404a and a n-doped N− region 404b. The N+ region 404a has a n type (e.g., doped with Phosphorus, Arsenic, and/or Antimony) doping level higher than the N− region 404b and is disposed under the top surface of the substrate 402 and embedded in the n− region 404b. Moreover, the drain region 406 may include a n-doped N+ region 406a and a n-doped N− region 406b both vertically aligned in the substrate 402. Specifically, the N− region 406b has a n type (e.g., doped with Phosphorus, Arsenic, and/or Antimony) doping level lower than the N+ region 406a and is disposed horizontally between the gate electrode 408 and the N+ region 406a. In some other embodiments, the string driver can be made of p-channel MOSFET, e.g., including a n type (e.g., doped with Phosphorus, Arsenic, and/or Antimony) doped substrate, and a p type (e.g., doped with Boron and/or Gallium) doped regions in the source 404 and the drain 406. The p-channel MOSFET may have P+ regions and P− regions in its source and drain, similar to the N+ regions and N− regions configurations in the source and drain regions of the n-channel MOSFET.

The string driver transistor shown in FIG. 4A is a voltage-controlled device configured to switch or amplify voltages in the string driver. It has four terminals including the gate electrode 408, the source region 404, the drain region 406, and the substrate (body) 402. The top surface of the substrate 402, i.e., the region below the gate oxide layer 410 and is located between the source region 404 and drain region 406 can be inverted from p-type to n-type by application of a positive gate voltage. In the example N-channel MOSFET shown in FIG. 4A, holes beneath the gate oxide layer 410 are pushed downward and a depletion region can be formed by the bound negative changers associated with acceptor atoms when applying the positive gate voltage. A channel between the source region 404 and the drain region 406 is then developed. In this scenario, current flows freely between the source and drain regions 404 and 406, and the gate voltage control the electrons in the channel. In other embodiments wherein the string driver contains p type doping regions in the source and drain, a negative voltage can be applied on the gate to form a hole channel under the gate oxide layer 410.

Each of the plurality of string drivers also includes a global word line (GWL) 414 that connects the string driver to a HV circuitry. The HV circuitry may be disposed in the incoming CMOS wafer and is connected to the string driver through various levels of metal layer interconnections. Specifically, as shown in FIG. 4A, the GWL 414 is connected to the N+ region 404a to transfer voltage signal from the HV circuitry to the source region of the string driver. In the present technology, the GWL 414 can be formed by etching the isolation material disposed above the MOSFET and filling in with electrically conductive materials including metal or metal alloys. Using the higher doped N+ region 404a for the connection could effectively reduce the contact resistance between the GWL 414 and the source region 404 of the MOSFET. Additionally, the lower doped N− region 404b supports most of the applied source voltage by providing a voltage drop region with increased on-resistance.

Further, each of the plurality of string drivers includes a local deep trench (LDT) region 412 that is disposed adjacent to the drain region 406 of the MOSFET shown in FIG. 4A. The LDT region 412 can be filled by electrically non-conductive materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. The LDT region 412 may have a thickness (e.g., close to 8 kÅ) close to or less than the n type doped drain region 406. As shown in FIG. 4A, at least a far end surface of the N+ region 406a is surrounded by the LDT region 412. In some embodiments, the LDT region 412 may further extend along a longitude direction of the MOSFET to surround other two sidewall surfaces of the drain region 406. Moreover, the incoming CMOS wafer 400 also includes shallow trench isolation (STI) regions (not shown) disposed between neighboring string driver transistors. Specifically, the STI regions may be disposed under the front side surface of the substrate 402 and between the paralleled gates of neighboring string driver transistors. The STI region may have a thickness close to or less then 4 kÅ in order to provide electrical isolation between adjacent string driver transistors.

In some other embodiments, each of the plurality of string drivers of the incoming CMOS wafer 400 can be made of other types of transistors, such as FinFET. For example, the substrate 402 can be a p type doped silicon fin of the FinFET extending along horizontal direction in the CMOS wafer 400. The gate electrode 408 can be disposed on a top surface and both sidewall surfaces of the fin 402. The source region 404 and the drain region 406 of the FinFET, having n type N+ regions and N− regions doping profiles similar to that of the MOSFET, can be disposed at both ends of the fin 402.

For the above-described string driver transistors, the gate electrode 408 as well as the gate oxide layer 410 can be fabricated prior to implantations of the N− regions 404b and 406b and N+ regions 404a and 406a, to server as a mask during the implantations, i.e., the source region 404 and the drain region 406 are self-aligned with respect to the gate electrode 408. In addition, the N− regions 404b and 406b of the source region and the drain region may laterally diffuse into the channel region under the gate electrode 408 during the implantation process or a thermal annealing process thereafter.

FIG. 4B depicts a schematic view of the CMOS wafer 400 and a memory array wafer 420 prior to the WOW bonding process according to embodiments of the present technology. Before the WOW bonding and further metal formation in the CMOS wafer 400, the CMOS wafer 400 is thinned on its backside by a suitable technique such as wafer back grinding to remove the bulk of excess substrate/wafer thickness. The CMOS wafer thinning process may stop at the bottom of the LDT region 412 such that the plurality of string drivers can be fully isolated by the LDT region 412. As described earlier, the STI regions of the plurality of string drivers have a thickness less than the LDT region 412, therefore the plurality of string drivers of the backside thinned CMOS wafer 400 still share a silicon bridge underneath the STI regions to prevent transistor floating body issues.

After the CMOS wafer backside thinning process, a dielectric layer 418, e.g., an oxide layer, can be deposited on the backside surface of the CMOS wafer. The oxide layer can be silicon oxide processed at a temperature close to or lower than 400° C. by a proper thin film deposition technique including chemical vapor deposition, physical vapor deposition, atomic layer deposition, plating, electroless plating, spin coating, and/or other suitable techniques. In this example, the dielectric layer may have a thickness ranging from 50 nm to 200 nm.

Once the dielectric layer 418 is deposited, the backside surface of the CMOS wafer 400 can be bonded to a frontside surface of the memory array wafer 420 through the WOW bonding process. In some embodiments, the memory array wafer 420 includes one or more memory arrays with a plurality of word lines each being connected to a metal pad 422. Moreover, the memory arrays (not shown) and corresponding metal pads 422 are encapsulated by a dielectric layer 424, e.g., an oxide layer, for electrical isolation.

In some other embodiments, the CMOS wafer 400 has a silicon-on-insulator (SOI) substrate. The CMOS wafer 400 backside thinning process can reduce the thickness of the CMOS wafer 400 until exposing the insulator, e.g., an oxide layer. The oxide layer of the SOI substrate can be bonded to the dielectric layer 424 of the memory array wafer for the WOW bonding.

In the present technology, the CMOS wafer 400 and the memory array wafer 420 can be bonded by forming dielectric-dielectric bonds (e.g., strong covalent bonds) between the dielectric layer 418 and the dielectric layer 424 without any gaps or voids. As shown in FIG. 4C, by applying heat and/or compression force to the WOW bonding, the dielectric layers 418 and 424 can be fused together. The WOW bonding shown on FIG. 4B also includes aligning metal pad 422 of each of the memory array word line to the drain region 406 of corresponding string driver transistor to accept the local word line (LWL) connection.

FIG. 4C depicts a schematic view of the WOW packaging including the CMOS wafer 400 and the memory array wafer 420 according to embodiments of the present technology. Specifically, the WOW packaging includes a LWL 418 that vertically passes through the string driver of the CMOS wafer 400 and that is connected to the corresponding metal pad 422 of the memory array wafer 420.

In some embodiments, the LWL 418 is configured to pass through the drain region 406 of the MOSFET, the dielectric-dielectric bonding interface, and connect to the metal pad 422. In the present technology, the LWL 418 can be formed by etching a hole through the encapsulating dielectric layer of the CMOS wafer 400, the drain region 406, and the dielectric layers 418 and 424 disposed between the drain region 406 and the metal pad 422. As shown in FIG. 4C, the hole may be entirely within interior of the N+ region 406a of the MOSFET drain for etch uniformity purposes. In this example, the hole can be etched by an anisotropic etching technique, e.g., a reactive ion etching (RIE) process, which stops at the metal pad 422, e.g., through an end point detection method.

In some other embodiments, the LWL 418 can partially pass through the N+ region 406a and partially pass through the adjacent LDT region 412. In this example, the etch of the hole can be conducted by a single anisotropic etch process or multiple selective etch processes for better etch uniformity control. For example, a silicon etch process selective to dielectric materials can be used to vertically etch a portion of the N+ region 406a and then a directional oxide etch process selective to silicon can be used to vertically etch a portion of the LDT region 412.

Once the hole is etched through the CMOS wafer and to the metal pad 422, standard silicon contact alloy can be formed on the sidewall of the hole. A metallization process can be conducted to fill electrically conductive material including metals or metal alloys into the hole to form the LWL 418. In the present technology, the top portion of the LWL 418 will not be connected to any other devices of the CMOS wafer 400. For example, the LWL 418 disposed above the MOSFET may be encapsulated by dielectric material or processed by a dual damascene process to maintain electrical isolation. Further, the gate electrode 408 may be connected to the HV circuitry with dedicated switches and passive components.

In some embodiments, a metal last process can be utilized to fabricate intermediate levels of metal layers in the CMOS wafer 400, through which the GWL 414 connects the HV circuitry and general circuit routing. Further, as shown in FIG. 4C, the LWL 418 is separated from the gate electrode 408 by the N− region 406b. Specifically, the N− region 406b is vertically disposed in the substrate 420 so as to isolate the N+ region 406a including the passing through LWL 418 from the gate electrode 406a. Here, the N− region 406b may have a width close to or larger than a minimum N+ region. In addition, the N+ region 406a can be configured to prevent shortage form the gate electrode 408 to the LWL 418 through degraded N− region 406a. Moreover, by passing through the N+ region 406a, the LWL 418 can achieve a low contact resistance.

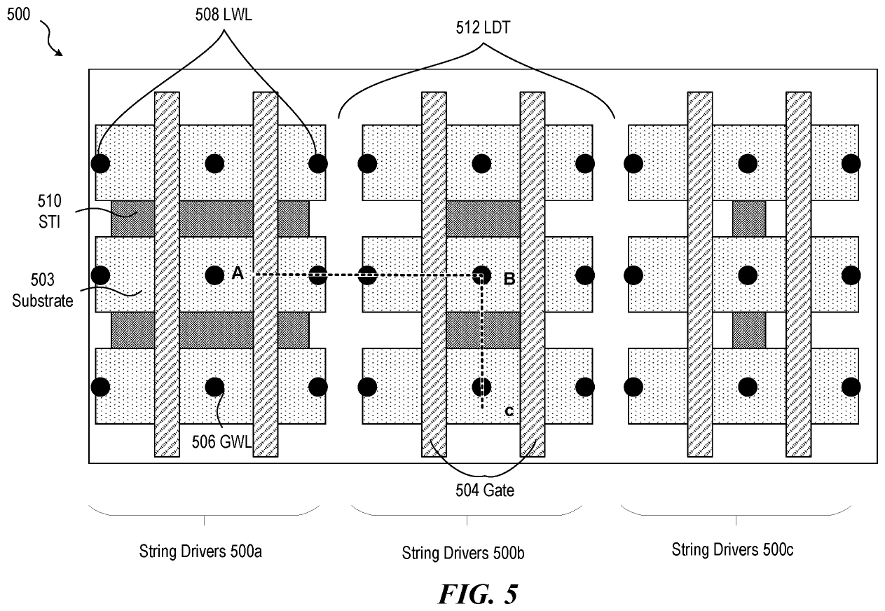

Now turning to FIG. 5 which depicts a plane view of string drivers 500 with various configurations according to embodiments of the present technology. Specifically, FIG. 5 illustrates a 3 by 3 device snippet from a larger string driver array. In this example, three columns of string drivers 500a, 500b, and 500c are aligned horizontally and separated by LDT regions 512. Within each of the string drivers columns, three pairs of string drivers are aligned in parallel and vertically separated by the STI regions 510. In addition, each of the vertically aligned string drivers shares a gate electrode 504. As shown in FIG. 5, each of the pair of the string drivers includes two transistors, e.g., MOSFET, having a shared source region. Moreover, each of the string drivers includes a GWL 506 connected to the source region of corresponding transistor and a LWL 508 connected to the drain region of corresponding transistor.

In some embodiments, the string drivers 500 are configured to have STI extends partially into the LWL region, as shown in string drivers 500a on the left column of FIG. 5. In this example, the vertically aligned pairs of string driver transistors are isolated by the STI regions 510. In addition, the STI region 510 extends partially into the LWL 508 regions, e.g., the LDT region 512 is partially overlapped with the LWL 508 along the longitude direction of the shared gate electrodes 504. Here, the drain region of each of the pairs of string driver transistors are partially surrounded by the LTD region 512.

In some other embodiments, the string drivers are configured to have STI extends partially into gate electrode, as shown in string drivers 500b on the middle column of FIG. 5. In this example, the vertically aligned pairs of string driver transistors are mainly isolated by the LDT regions 512. Particularly, the STI region 510 extends partially into the gate electrodes 504, meaning the laterally outer edges of the STI regions 510 are overlapped to the gate electrodes 504. In this example, the LDT region 512 surrounds not only the complete drain regions but also a portion of the gate regions of the string driver transistors.

In some other embodiments, the string drivers are configured to have STI ends in the GWL area, as shown in string drivers 500c on the right column of FIG. 5. In this example, the STI region has a limited length (or leaves only a sliver) along the longitude direction of the pair of string drivers, i.e., close to or smaller than a diameter of the GWL 506. As shown, the vertically aligned pairs of string driver transistors are mainly isolated by the LDT regions 512. Here, the LDT regions 512 completely surrounds the drain region, the gate region, and a portion of the shared source region of the string driver transistors.

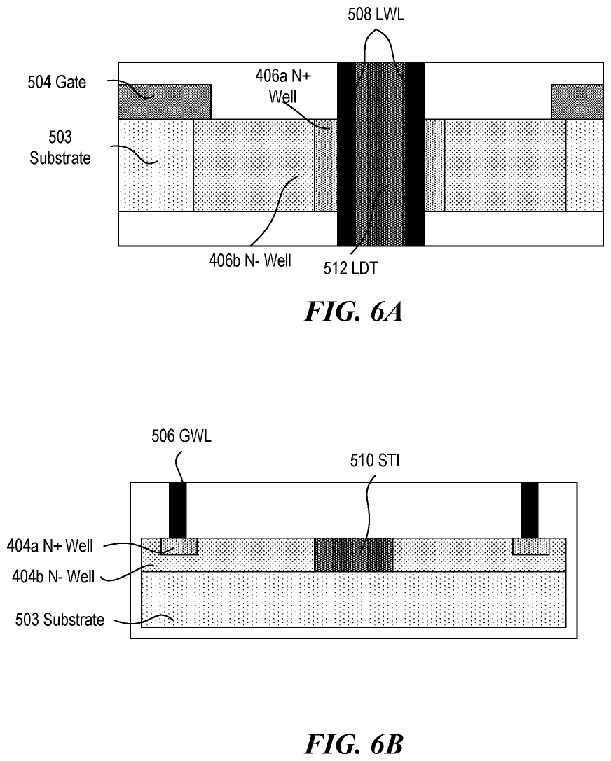

FIG. 6A depicts a cross-sectional view of string drivers along the A-B plane of FIG. 5 according to embodiments of the present technology. Specifically, FIG. 6A illustrates neighboring string driver transistors having LWLs passing through corresponding drain regions and isolated by LDT region 512. In this example, each of the neighboring string driver transistors has a gate electrode 504, a source region (not shown), a substrate 503, and a drain region 406. As described, the drain regions of each of the string driver transistor includes a lower-level doped N− region 406b and a higher level doped N+ region 406a, both of which are vertically aligned in the substrate 503 and the N− region 406b being disposed closer to the gate electrode 504 in order to prevent vertical voltage drop between the gate and the N+ drain region. In the present technology, the LWLs 508 are configured to vertically pass through the drain regions of the neighboring string driver transistors, so as to transfer a control voltage from the HV circuitry to corresponding word lines of the memory array. As shown, the LDT region 512 completely isolates the active regions of neighboring string driver transistors, e.g., the N+ drain regions 406b, and the LWL 508 passing there through. Further, the LWL contact is located along the LWL 508 sidewall for the full depth of the N+ drain region 406a of the backside thinned CMOS wafer 400, and continues towards to the dielectric-dielectric bonding interface of the WOW bonding. Compared to traditional string drivers which have LWLs passing through the isolation regions between neighboring string driver transistors, the present technology better utilizes the drain region of the string driver transistors, to achieve a higher string driver device density on the CMOS wafer for WOW packaging.

FIG. 6B depicts a cross-sectional view of string drivers along the B-C plane of FIG. 5 according to embodiments of the present technology. Particularly, FIG. 6B illustrates string drivers aligned in parallel and having GWL 506 connected to the top of corresponding N+ source region 404a. As shown, the string drivers aligned in parallel are partially isolated by the STI region 510. In this example, the STI region 510 has a depth similar to the N− source region 404b and does not further extend into the substrate 503 of the string driver transistor. With this configuration, the STI region 510 can isolate adjacent active source regions (e.g., N− regions 404b) to prevent shortage between transistors. In addition, the substrate 503 (e.g., a p type doped substrate in the MOSFET of CMOS wafer 400) extends between parallelly aligned string driver transistors and under the STI region 510. A transistor floating body issue can be prevented through grounding or biasing the bridged substrate 503 to a certain voltage.

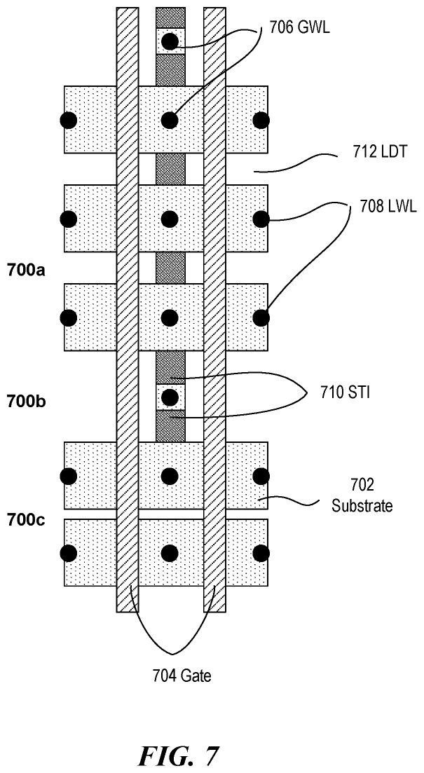

Now turning to FIG. 7 which depicts a plane view of a column of pairs of string drivers having various STI and LDT configurations according to embodiments of the present technology. In this example, a plurality of parallelly aligned pairs of string driver transistors are aligned vertically and are isolated by STI and LDT in different patterns. In particular, this column of string drivers illustrate three types of isolations 700a, 700b, and 700c.

The string driver isolation 700a has a medium active spacing with STI 710 isolation. As shown and in some embodiments, the isolation 700a includes STI region 710 that ends in the GWL area 706. The LDT region 712 completely surrounds the drain region, the gate region, and a portion of the source region of parallelly aligned string driver transistors. Here, the silicon bridge connection between the parallelly aligned string driver transistors are limited below the STI region 710 of the isolation 700a. In this example, the isolation between parallelly aligned string driver transistors is limited by an ability to suppress punch-through underneath the STI region 710 and to sustain a high break down voltage.

In some other embodiments, the isolation 700b includes a wide active spacing with STI regions 710 and a silicon body connection disposed therebetween. As shown, the isolation 700b between the parallelly aligned string driver transistors has a larger space compared to the medium active spacing 700a. In addition, the isolation 700b includes a substrate 702 connected by a GWL 706. The substrate 702 of the isolation 700b is further isolated by STI regions 710 disposed above its top edge and below its bottom edge from the parallelly aligned upper and lower string driver transistors, respectively. In this example, the STI region 710 disposed above the top edge and below the bottom edge of the substrate 702 has a width close to the diameter of the GWL 706. This isolation 700b may be applicable to applications that must isolate body connection from the string driver device, specifically for the GWL connections.

In some other embodiments, the isolation 700c includes a narrow active spacing using the LDT 712. As shown, the parallelly aligned string drivers are completely isolated by LDT 712 without any silicon body/substrate bridge connections therebetween. In this example, the spacing between parallelly aligned string driver transistors is limited by the dielectric breakdown between adjacent active regions, e.g., neighboring source regions between the parallelly aligned string driver transistors. Another factor that may limit the narrow active spacing in the isolation 700c is capacitive coupling effect that may be generated between parallelly aligned string driver transistors and across the isolation region 700c.

It is worth to note that the above-described isolations 700a, 700b, and 700c can be disposed between parallelly aligned string driver transistors with various patterns. For example, an alternating pattern of “700b-700c-700b-700c” isolations disposed vertically in the string drivers device region can be formed to present H-shaped structures surrounded by LDT regions 712, in which the average of 700b and 700c active spacings are acceptable to the design rules. This configuration may provide an opportunity for body biasing to improve the string driver performance, e.g., applying a positive voltage to the bridged body/substrate to reduce the floating body effect in the string driver transistors. In another example, the string drivers device regions can include periodic body contacts such as a pattern of “700a-700a-700b-700a-700a” being disposed between the vertically aligned string driver transistors.

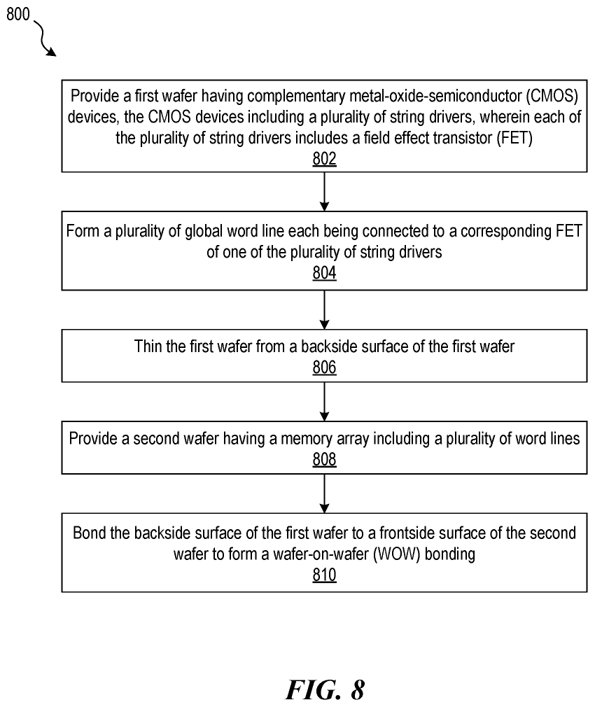

FIG. 8 is a flow chart illustrating a method 800 of processing the WOW bonding for semiconductor device assembly according to embodiments of the present technology. For example, the method 800 includes providing a first wafer having complementary metal-oxide-semiconductor (CMOS) devices, the CMOS devices including a plurality of string drivers, wherein each of the plurality of string drivers includes a field effect transistor (FET), at 802. For example, the CMOS wafer 400 is provided for the WOW bonding as shown in FIG. 4A. The CMOS wafer 400 includes a plurality of string driver devices each having a MOSFET transistor. Moreover, the MOSFET of each of the plurality of string driver devices includes a gate electrode 410, a source region 404, a drain region 406, and a substrate/body 402. In some other examples, the transistor included in the string driver devices can be a FinFET.

The method 800 also includes forming a plurality of global word line each being connected to a corresponding FET of one of the plurality of string driver, at 804. For example, each of the plurality of string driver devices shown in FIG. 4A includes a GWL 414 that is connected to the source region of the MOSFET. Specifically, the GWL 414 can be connected to the high doped N+ region 404a of the MOSFET to form a low resistance contact there between.

In addition, the method 800 includes thinning the first wafer from a backside surface of the first wafer, at 806. For example, the CMOS wafer 400 can be thinned from its backside surface by a suitable technique such as wafer back grinding to remove the bulk of excess substrate/wafer thickness. The wafer backside thinning process may stop at the LDT region 412 of the CMOS wafer 400. In some other examples and after the wafer backside thinning process, a dielectric layer such as dielectric layer 418 can be deposited on the backside surface of the CMOS wafer 400.

Further, the method 800 includes providing a second wafer having a memory array including a plurality of word lines, at 808. For example, the memory array wafer 420 can be provided for the WOW bonding. As described on FIG. 4B, the memory array wafer 420 may include one or more memory arrays each having a plurality of word lines, each of the word lines is connected to a corresponding metal pad 422 for the LWL connection. Further, the one or more memory arrays are encapsulated by the dielectric layer 424 that is disposed at the frontside surface of the memory array wafer 422.

Lastly, the method 800 includes bonding the backside surface of the first wafer to a frontside surface of the second wafer to form a WOW bonding, at 810. For example, a dielectric-dielectric bonding, (e.g., an oxide-oxide diffusion bonding) can be formed between the dielectric layers 418 and 424. Heat and/or compression force may be applied to the WOW bonding to form strong covalent bonds between the CMOS wafer 400 and memory array wafer 420.

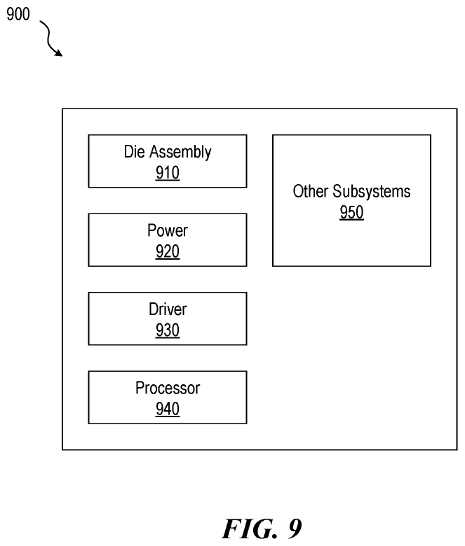

Any one of the semiconductor structures described above with reference to FIGS. 1-7 can be incorporated into any of a myriad of larger and/or more complex systems, a representative example of which is system 900 shown schematically in FIG. 9. The system 900 can include a semiconductor device 910, a power source 920, a driver 930, a processor 940, and/or other subsystems or components 950. The semiconductor device 910 can include features generally similar to those of the semiconductor devices described above and can therefore include the string drivers connections and the string driver direct contact described in the present technology. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, and appliances. Components of the system 900 may be housed in a single unit or distributed over multiple, interconnected units (e.g., through a communications network). The components of the system 900 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first wafer having complementary metal-oxide-semiconductor (CMOS) devices, the CMOS devices including a plurality of string drivers, wherein each of the plurality of string drivers includes a field effect transistor (FET), a global word line connected to a source of the FET, and a local word line vertically passing through the FET; and
a second wafer having a memory array including a plurality of word lines, each of the word lines being connected to a corresponding one of the string drivers of the first wafer through a local word line of the corresponding string driver;
wherein a backside surface of the first wafer is bonded to a frontside surface of the second wafer to form a wafer-on-wafer (WOW) bonding.

2. The semiconductor device assembly of claim 1, wherein the FET of each of the plurality of string drivers of the first wafer is a metal-oxide-semiconductor FET (MOSFET) including a gate, a source, and a drain.

3. The semiconductor device assembly of claim 2, wherein the global word line of each of the plurality of string drivers is connected to the source of the MOSFET, and wherein the local word line of each of the plurality of string drivers vertically passes through at least a portion of the drain of the MOSFET.

4. The semiconductor device assembly of claim 3, wherein the drain of the MOSFET of each of the plurality of string drivers includes a lightly doped drain region and a heavily doped drain region, both of which vertically extend through a substrate of the MOSFET, wherein the lightly doped drain region is disposed between the gate of the MOSFET and the heavily doped drain region of the MOSFET.

5. The semiconductor device assembly of claim 4, wherein the local word line of each of the plurality of string drivers vertically passes through the heavily doped drain region of corresponding MOSFET.

6. The semiconductor device assembly of claim 4, wherein the first wafer includes a plurality of local deep trench (LDT) regions comprising dielectric materials, each of the plurality of LDT regions being disposed adjacent to the heavily doped drain region of corresponding one of the plurality of string drivers.

7. The semiconductor device assembly of claim 6, wherein the local word line of each of the plurality of string drivers vertically passes through the heavily doped drain region and adjacent LDT region of corresponding one of the plurality of string drivers.

8. The semiconductor device assembly of claim 2, wherein the source of the MOSFET of each of the plurality of string drivers includes a lightly doped source region and a heavily doped source region, the heavily doped source region being embedded in the lightly doped source region, and wherein the global word line of each of the plurality of string drivers is connected to the heavily doped source region of the corresponding string driver.

9. The semiconductor device assembly of claim 1, wherein the first wafer comprise a dielectric layer disposed at the backside surface of the first wafer and below the plurality of string drivers, and wherein the dielectric layer of the first wafer is bonded to a dielectric layer disposed at the frontside surface of the second wafer to form the WOW bonding.

10. The semiconductor device assembly of claim 1, wherein the local word line of each of the plurality of string drivers vertically passes through the first wafer including the corresponding FET of the string driver and the dielectric layer of the first wafer, and wherein the local word line of each of the plurality of string drivers is further extended into the second wafer through the WOW bonding interface and is connected to a metal pad, the metal pad being connected to a corresponding word line of the memory array of the second wafer.

11. A semiconductor device, comprising:
a gate disposed at least on a top surface of a substrate;
a source disposed at one end of the gate and in the substrate, the source having a lightly doped source region and a heavily doped source region, wherein the heavily doped source region is embedded in the lightly doped source region;
a drain disposed at another end of the gate and in the substrate, the drain having a lightly doped drain region and a heavily doped drain region, both of which vertically extend through a substrate of the semiconductor device;
wherein the lightly doped drain region is disposed between the gate and the heavily doped drain region.

12. The semiconductor device of claim 11, further comprising:
a global word line that is connected to the heavily doped source region of the semiconductor device; and
a local word line that vertically passes through the drain of the semiconductor device.

13. The semiconductor device of claim 12, wherein the local word line vertically passes through the heavily doped drain of the semiconductor device.

14. The semiconductor device of claim 12, further comprising a local deep trench (LDT) region comprising dielectric materials, the LDT region being disposed adjacent to the heavily doped drain region of the semiconductor device, wherein the local word line vertically passes through the heavily doped drain region and adjacent LDT region of the semiconductor device.

15. The semiconductor device of claim 14, further comprising a shallow trench isolation (STI) region comprising dielectric materials, the STI region being adjacent to and in parallel to the gate of the semiconductor device, wherein the STI region has a depth less than the LDT region.

16. A method of forming a semiconductor device assembly, comprising:
providing a first wafer having complementary metal-oxide-semiconductor (CMOS) devices, the CMOS devices including a plurality of string drivers, wherein each of the plurality of string drivers includes a field effect transistor (FET);
forming a plurality of global word line each being connected to a corresponding FET of one of the plurality of string drivers;
thinning the first wafer from a backside surface of the first wafer;
providing a second wafer having a memory array including a plurality of word lines; and
bonding the backside surface of the first wafer to a frontside surface of the second wafer to form a wafer-on-wafer (WOW) bonding.

17. The method of forming a semiconductor device assembly of claim 16, wherein providing the first wafer comprises:
forming a gate at least on a top surface of a substrate of each of the plurality of string drivers;
forming a source at one end of the gate and in the substrate, the source having a lightly doped source region and a heavily doped source region, wherein the heavily doped source region is embedded in the lightly doped source region; and
forming a drain disposed at another end of the gate and in the substrate, the drain having a lightly doped drain region and a heavily doped drain region, both of which vertically extend through a substrate of the semiconductor device,
wherein the lightly doped drain region is disposed between the gate and the heavily doped drain region.

18. The method of forming a semiconductor device assembly of claim 17, wherein providing the first wafer further comprises:
forming a local deep trench (LDT) region comprising dielectric materials in the substrate of each of the plurality of string drivers, the LDT region being disposed adjacent to the heavily doped drain region of the semiconductor device; and
forming a shallow trench isolation (STI) region comprising dielectric materials in the substrate of each of the plurality of string drivers, the STI region being adjacent to and in parallel to the gate of the semiconductor device, wherein the STI region has a depth less than the LDT region.

19. The method of forming a semiconductor device assembly of claim 18, further comprising forming a plurality of local word lines passing through the plurality of string drivers, respectively, wherein the plurality of local word lines further pass through the WOW bonding interface and extend into the second wafer, and wherein each of the plurality of local word lines is connected to a corresponding one of a plurality of metal pads in the second wafer, the plurality of metal pads being respectively connected with the plurality of word lines of the memory array in the second wafer.

20. The method of forming a semiconductor device assembly of claim 19, wherein each of the plurality of local word lines at least partially passes through the heavily doped drain region of corresponding one of the plurality of string drivers.
